(19) United States
(12) Patent Application Publication
(10) Pub. No.: US 2009/0243002 A1
(43) Pub. Date: Oct. 1, 2009

(54) SEMICONDUCTOR DEVICE AND METHOD OF FABRICATING THE SAME

(75) Inventors: Takeshi SONEHARA, Kanagawa (JP); Akira HOKAZONO, Kanagawa (JP); Haruko AKUTSU, Kanagawa (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 12/410,560

(22) Filed: Mar. 25, 2009

(30) Foreign Application Priority Data
Mar. 28, 2008 (JP) 2008-086029

(51) Int. Cl. H01L 29/78; H01L 21/336

(52) U.S. Cl. 257/413; 438/197; 257/E29.255; 257/E21.409

(57) ABSTRACT

A semiconductor device according to one embodiment includes: a semiconductor substrate; a gate electrode formed on the semiconductor substrate via a gate insulating film; a first silicide layer formed on the gate electrode; a channel region formed in the semiconductor substrate below the gate electrode; source/drain regions formed in regions in the semiconductor substrate, the regions sandwiching the channel region; and second silicide layers formed on the source/drain regions and having an average grain size smaller than that of the first silicide layer or an average number of compositional boundaries in a crystal grain larger than that of the first silicide layer.

### CROSS-REFERENCE TO RELATED APPLICATIONS

This application is based upon and claims the benefit of priority from prior Japanese Patent Application No. 2008-086029, filed on Mar. 28, 2008, the entire contents of which are incorporated herein by reference.

### BACKGROUND

A conventional semiconductor device is known in which a metal silicide layer is provided on surfaces of a gate electrode and source/drain regions in order to lower contact resistance of the gate electrode and the source/drain regions. This conventional semiconductor device, for example, is disclosed in JP-A-2007-214269.

In this semiconductor device, a first metal layer is formed on a semiconductor substrate, a second metal layer is formed so as to cover the first metal layer, a silicidation reaction is generated between the first and second metal layers by first heat treatment, non-silicided portions of first and second metal layers are removed by etching, and a silicidation reaction is generated between at least one of the first and second metal layers and a semiconductor region containing Si by second heat treatment under temperature conditions higher than the first heat treatment, thereby obtaining a metal silicide layer of which grain size is small and uniform.

### BRIEF SUMMARY

A semiconductor device according to one embodiment includes: a semiconductor substrate; a gate electrode formed on the semiconductor substrate via a gate insulating film; a first silicide layer formed on the gate electrode; a channel region formed in the semiconductor substrate below the gate electrode; source/drain regions formed in regions in the semiconductor substrate, the regions sandwiching the channel region; and second silicide layers formed on the source/drain regions and having an average grain size smaller than that of the first silicide layer or an average number of compositional boundaries in a crystal grain larger than that of the first silicide layer.

A method of fabricating a semiconductor device according to another embodiment includes: forming a gate electrode on a semiconductor substrate via a gate insulating film; selectively forming a first silicide layer on the gate electrode; forming a channel region in the semiconductor substrate below the gate electrode; forming source/drain regions in regions in the semiconductor substrate, the regions sandwiching the channel region; and selectively forming second silicide layers on the source/drain regions, wherein the second silicide layers have an average grain size smaller than that of the first silicide layer or an average number of compositional boundaries in a crystal grain larger than that of the first silicide layer.

### BRIEF DESCRIPTION OF THE DRAWING

FIG. 1 is a cross sectional view showing a semiconductor device according to a first embodiment;

FIGS. 2A to 2E are conceptual views showing a crystal grain composing a second silicide layer;

FIG. 3 is a graph showing an example of a grain size variation and a resistance value variation with respect to a concentration of a second metal element mixed in the silicide layer;

FIGS. 4A and 4B are graphs showing a variation of parasitic resistance in the periphery of the silicide layer in source/drain regions;

FIG. 5 is a graph showing a relation between the concentration of the second metal element with respect to that of a first metal element in the silicide layer and sheet resistance of the silicide layer when the silicide layer is heated to 650° C.;

FIGS. 6A to 6F are cross sectional views showing processes for fabricating the semiconductor device according to the first embodiment;

FIGS. 7A to 7C are cross sectional views showing processes for fabricating a semiconductor device according to a second embodiment;

FIGS. 8A to 8C are cross sectional views showing processes for fabricating a semiconductor device according to a third embodiment; and

FIGS. 9A to 9C are cross sectional views showing processes for fabricating a semiconductor device according to a fourth embodiment.

### DETAILED DESCRIPTION

### First Embodiment

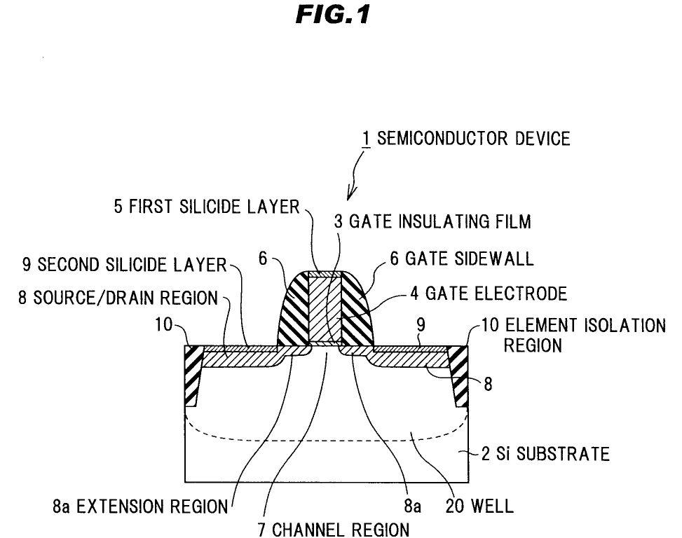

FIG. 1 is a cross sectional view showing a semiconductor device according to a first embodiment. A semiconductor device 1 is schematically configured to have a well 20 formed on a Si substrate 2, a gate electrode 4 formed on the Si substrate 2 via a gate insulating film 3, a first silicide layer 5 formed on an upper surface of the gate electrode 4, gate sidewalls 6 formed on side faces of the gate electrode 4, a channel region 7 formed in the Si substrate 2 below the gate electrode 4, source/drain regions 8 including extension regions 8a formed in the vicinity of a surface of the Si substrate 2, second silicide layers 9 formed on upper surfaces of the source/drain regions 8, and an element isolation region 10 formed in the Si substrate 2.

The gate insulating film 3 is made of, e.g., SiO₂, SiN, SiON, or a high-dielectric material (e.g., an Hf-based material such as HfSiON, HfSiO or HfO, etc., a Zr-based material such as ZrSiON, ZrSiO or ZrO, etc., and a Y-based material such as Y₂O₃, etc.).

The gate electrode 4 is made of, e.g., polycrystalline silicon containing a conductivity type impurity or polycrystalline silicon germanium containing a conductivity type impurity. As for the conductivity type impurity, a p-type impurity ion such as B or BF₂, etc., is used for a p-type transistor and an n-type impurity ion such as As or P, etc., is used for an n-type transistor. In addition, the first silicide layer 5 is formed on the upper surface of the gate electrode 4.

The gate sidewall 6 may have, e.g., a single layer structure made of SiN, a structure of two layers made of multiple types of insulating material comprising SiN, SiO₂ or TEOS (Tetraethoxysilane), etc., furthermore, may have a structure of three or more layers.

The source/drain regions 8 including the extension regions 8a are formed by implanting an impurity ion into the vicinity of the surface of the Si substrate 2. For a p-type transistor, a p-type impurity ion such as B or BF₂, etc., is implanted, and for an n-type transistor, an n-type impurity ion such as As or P, etc., is implanted.

The element isolation region 10 is made of, e.g., an insulating material such as SiO₂, etc.

At least a portion of crystal grains composing the second silicide layer 9 contains a crystallite of a compound of a first metal element and Si and a crystallite of a compound of a second metal element and Si.

At least a portion of crystal grains composing the first silicide layer 5 contains a crystallite of the compound of the first metal element and Si. Alternatively, at least a portion of the crystal grains composing the first silicide layer 5 may include a crystallite of the compound of the second metal element and Si as well as a crystallite of the compound of the first metal element and Si. Note that, although the first silicide layer 5 is formed by siliciding the upper surface of the gate electrode 4, a full silicide gate electrode may be formed by siliciding the whole gate electrode 4.

Here, a crystal structure of a silicide compound of the second metal element and Si is preferably equivalent to a crystal structure of a silicide compound of the first metal element and Si. In addition, an atomic radius of the second metal element is preferably larger than that of the first metal element. Furthermore, the first and second metal elements are preferably each selected from elements in different periods on the periodic table so that silicide having a composition containing both of the first and second metal elements becomes unlikely to be formed. For example, a fourth-period element is used as a first metal element and a fifth or sixth-period element having an atomic radius larger than that of the first metal element is used as a second metal element. In more detail, an element selected from Ti, V, Co and Ni is used as the first metal element, and an element selected from Ru, Rh, Pd, In, Ir and Pt is used as the second metal element.

The first silicide layer 5 on the gate electrode 4 is preferably a silicide layer with low resistance for the purpose of not deteriorating AC Characteristics. As described later, when a concentration of the second metal element contained in silicide increases, electrical resistance of the silicide increases. Therefore, from the viewpoint of the AC characteristics, a ratio of a number of atoms of the second metal element to a number of atoms of the first metal element in the first silicide layer 5 is preferably smaller than that in the second silicide layer 9. In addition, the ratio of the number of atoms of the second metal element to the number of atoms of the first metal element in the first silicide layer 5 is preferably 5 at % (atomic percentage) or less, more preferably, substantially 0 At %.

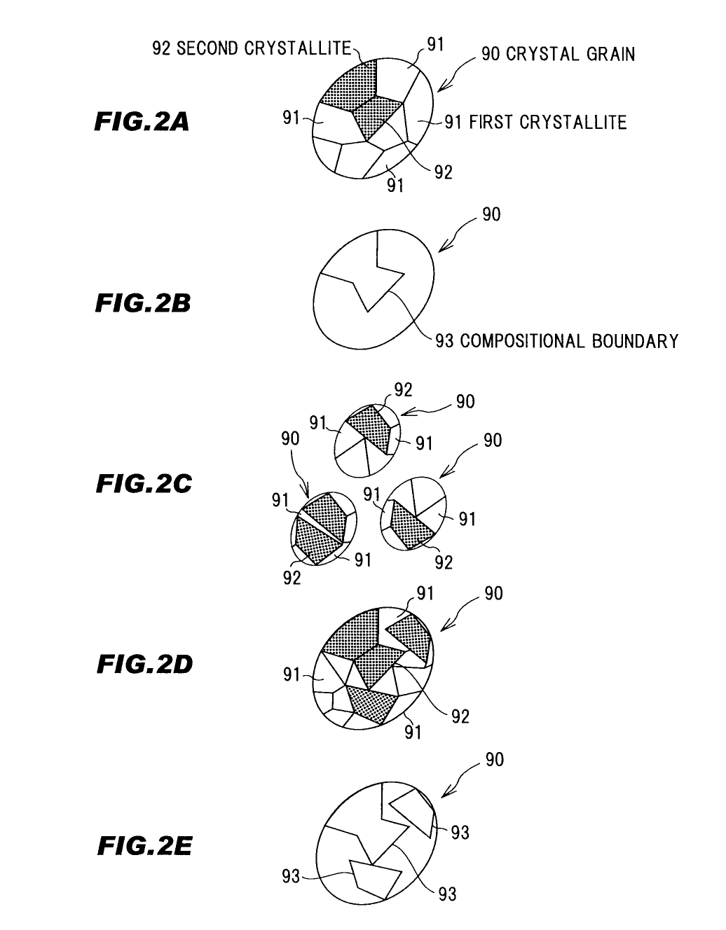

FIG. 2A is a conceptual view showing a crystal grain 90 composing the second silicide layer 9. The crystal grain 90 contains a first crystallite 91 and a second crystallite 92. The first crystallite 91 is a crystallite of a compound crystal of the first metal element and Si (e.g., a NiSi crystal), and the second crystallite 92 is a crystallite of a compound crystal of the second metal element and Si (e.g., a PtSi crystal). Here, as shown in FIG. 2B, a boundary between a group of the adjacent first crystallites 91 and a group of the adjacent second crystallites 92 is a compositional boundary 93.

As shown in FIG. 2C, when a concentration of the second metal element contained in the silicide layer increases, a grain size of the crystal grain 90 tends to decrease. When the grain size decreases, a crystal grain boundary area increases. Therefore, a diffusion of an impurity such as the second metal element or a dopant, etc., contained in the silicide layer is enhanced, and thus, the impurity is likely to segregate at the interface between the silicide layer and the source/drain region. In addition, a silicide layer with excellent film formability is obtained by diminution of grain size of the crystal grain 90.

In addition, as shown in FIG. 2D, when the concentration of the second metal element contained in the silicide layer increases, a ratio of the second crystallite 92 contained in the crystal grain 90 increases. When a ratio of the second crystallite 92 in the crystal grain 90 increases as shown in FIG. 2D, a dimension of the compositional boundary 93 or the number of the compositional boundaries 93 in an arbitrary cut surface of the crystal grain 90 increases as shown in FIG. 2E. Since the impurity such as the second metal element or a dopant contained in the silicide layer is diffused along the compositional boundary 93 or the crystal grain boundary, when a area of the compositional boundary 93 in each crystal grain 90 or the number of the compositional boundaries 93 in an arbitrary cut surface of the crystal grain 90 increases, the diffusion of the impurity is enhanced and the impurity is likely to segregate at the interface between the silicide layer and the source/drain region.

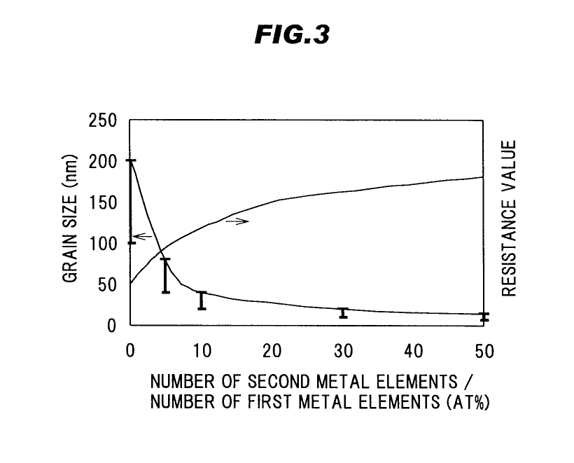

FIG. 3 is a graph showing an example of a relation between a concentration of the second metal element with respect to the first metal element in the silicide layer and a grain size, and a relation between the concentration of the second metal element with respect to the first metal element in the silicide layer and a resistance value. Data of silicide containing the first metal element such as Ni, etc., and the second metal element such as Pt, etc., is shown here.

As shown in FIG. 3, when the concentration of the second metal element increases with respect to the first metal element, miniaturization of the grain size is enhanced and, accordingly, dispersion of the grain size is diminished. By miniaturizing the crystal grain of the silicide layer, while it is possible to suppress abnormal film formation of the silicide and the formation of a leak current path, a resistance value in the silicide layer shows a tendency of increasing.

From the viewpoint of leak current suppression, the ratio of the number of atoms of the second metal element to the number of atoms of the first metal element in the second silicide layer 9 is preferably 5 At % or more. For specifically suppressing the resistance value to be low, the ratio of the number of atoms of the second metal element to the number of atoms of the first metal element in the second silicide layer 9 is not less than 5 at %, and preferably as small as possible. In addition, an average grain size of the silicide obtained by adding the second metal element is preferably 100 nm or less, and more preferably, the grain size is 20 nm or less in a region of 80% or more of the second silicide layers 9 that are formed on the upper surfaces of the source/drain regions 8.

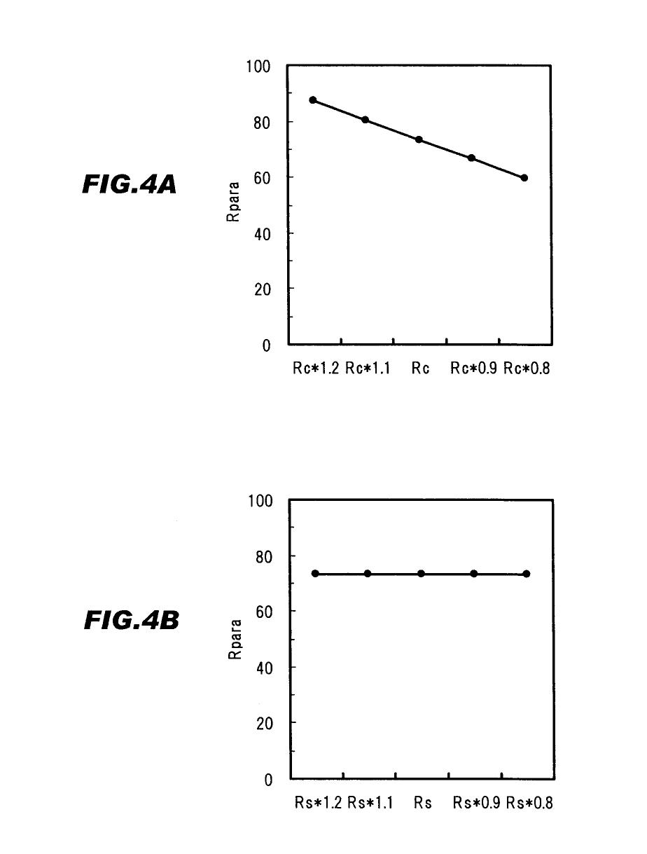

FIG. 4A is a graph showing a relation between parasitic resistance (Rpara) in the source/drain regions in the periphery of the silicide layer and interface resistance (Rc) of the silicide layer. In addition, FIG. 4B is a graph showing a relation between the parasitic resistance (Rpara) in the source/drain regions in the periphery of the silicide layer and sheet resistance (Rs) of the silicide layer. The sheet resistance here shows a resistance value between two arbitrary points in the second silicide layer 9. As described above, when the second metal element, a conductivity type impurity contained in the source/drain regions 8 and an impurity inevitably contained in the Si substrate 2 are segregated at the interface between the Si substrate 2 and the second silicide layers 9, the interface resistance (Rc) is reduced due to modulation of work function at the interface or increase of an impurity concentration at the interface, thereby reducing the parasitic resistance (Rpara) in the periphery of the silicide layer. This reduction of the parasitic resistance (Rpara) occurs more remarkably than the case of reducing the sheet resistance of the silicide layer as shown in FIG. 4B. Namely, even when the sheet resistance of the second silicide layer 9 increases due to the miniaturization of the crystal grain by adding the second metal element, the reduction of the interface resistance (Rc) is promoted. It is thereby possible to reduce the parasitic resistance (Rpara) in the periphery of the silicide layer.

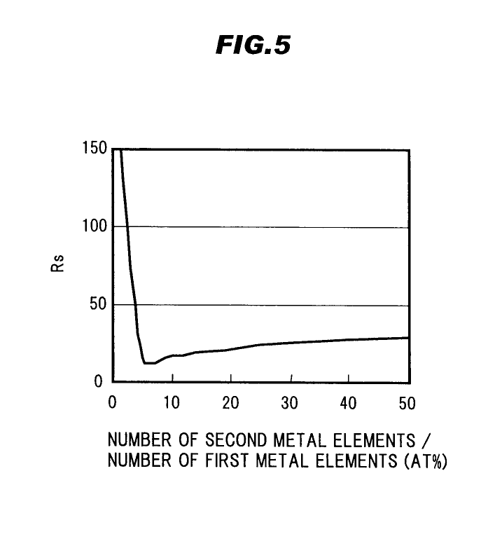

FIG. 5 is a graph showing a relation between a concentration of the second metal element with respect to that of the first metal element in the silicide layer and the sheet resistance (Rs) of the silicide layer when the silicide layer is heated to 650° C. As shown in FIG. 5, when the ratio of the number of atoms of the second metal element to that of the first metal element in the silicide layer is less than 7 at %, the sheet resistance (Rs) becomes large compared with the case of 7 at % or more. If the sheet resistance (Rs) increases, the electrical resistance of the silicide layer may increase due to disconnection of the silicide layer.

From this result, the ratio of the number of atoms of the second metal element to that of the first metal element in the second silicide layer 9, which has a large surface area and is easily disconnected, is preferably 7 at % or more from the view point of heat resistance. Since heat applied to the second silicide layer 9 during the process of fabricating the semiconductor device 1 is at a temperature of 650° C. or less, it is sufficient if the ratio of the number of atoms of the second metal element to that of the first metal element in the first silicide layer 5 and the ratio in the second silicide layer 9 are 7 at % or more.

In accordance with above results, a ratio of the number of atoms of the second metal element to the number of atoms of the first metal element in the first silicide layer 5 is preferably smaller than that in the second silicide layer 9, and more preferably, 5 at % or less from the viewpoint of the AC characteristics. Furthermore, the ratio of the number of atoms of the second metal element to that of the first metal element in the second silicide layer 9 is preferably 7 at % or more from the viewpoint of the leak current suppression and the heat resistance.

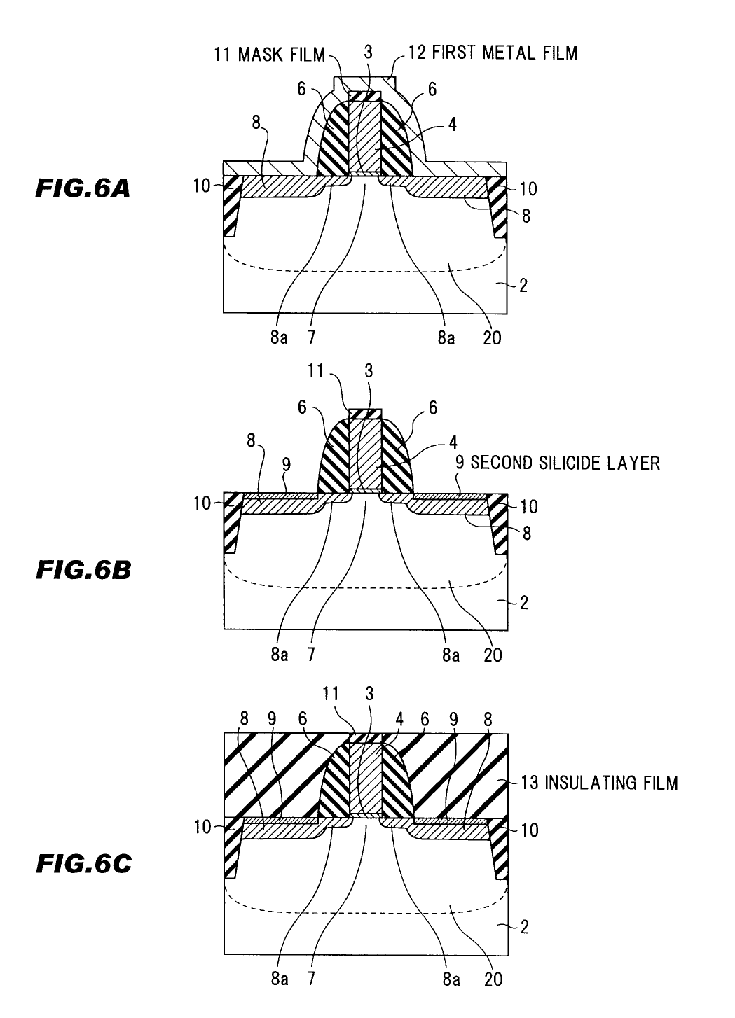

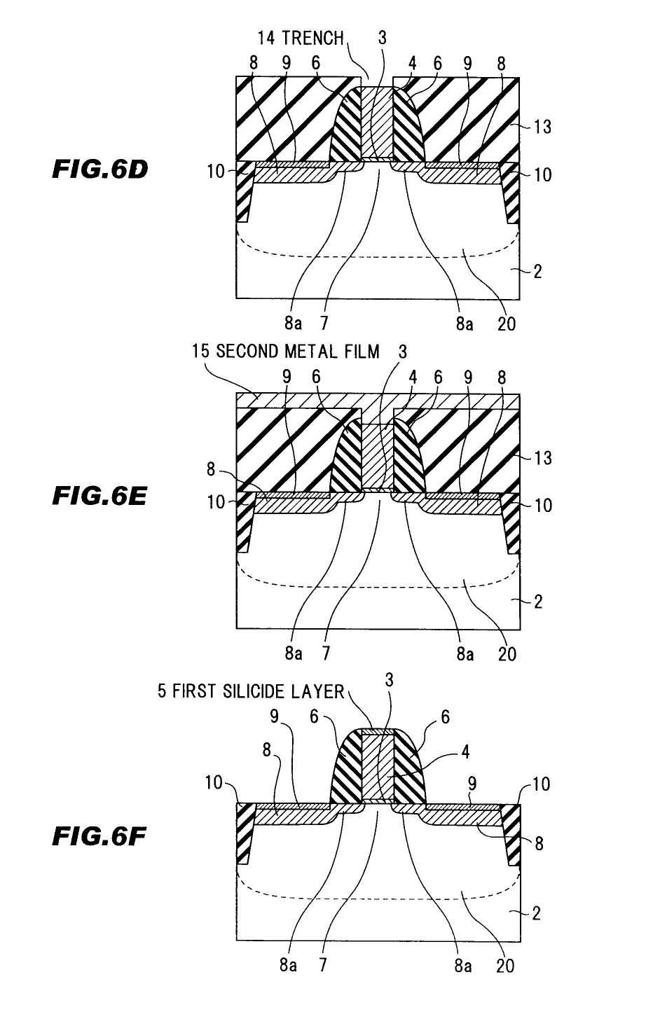

FIGS. 6A to 6F are cross sectional views showing processes for fabricating the semiconductor device according to the first embodiment.

Firstly, as shown in FIG. 6A, the element isolation region 10, the gate insulating film 3, the gate electrode 4, the source/drain regions 8 including extension regions 8a and the gate sidewalls 6, etc., are formed on the Si substrate 2. Then, a mask film 11, which is, e.g., an oxide film made of SiO₂ or a nitride film made of SiN, etc., having high etching selectivity with respect to Si, is formed on the gate electrode 4. Next, a first metal film 12 containing the first metal element such as Ni, etc., and the second metal element such as Pt, etc., is deposited by sputtering so as to cover exposed portions of upper surfaces of the source/drain regions 8, the element isolation region 10, the gate sidewalls 6 and the mask film 11.

Next, as shown in FIG. 6B, the second silicide layers 9 are formed on the upper surfaces of the source/drain regions 8 by a silicidation reaction between the first metal film 12 and the source/drain regions 8 by carrying out RTA (Rapid Thermal Annealing) at 400-500° C. Subsequently, unreacted portions of first metal film 12 are removed by a mixed solution of sulfuric acid and hydrogen peroxide solution, or aqua regalis (a mixture of nitric acid and hydrochloric acid).

Next, as shown in FIG. 6C, an insulating film 13 such as SiO₂ is deposited by a CVD (Chemical Vapor Deposition) method, etc., so as to cover the exposed portions of the upper surfaces of the source/drain regions 8 having the second silicide layers 9 formed thereon, the element isolation region 10, the gate sidewalls 6 and the mask film 11. Next, the insulating film 13 is planarized by CMP (Chemical Mechanical Polishing), etc., until the mask film 11 is exposed.

Next, as shown in FIG. 6D, the mask film 11 covering the upper surface of the gate electrode 4 is removed by a RIE (Reactive Ion Etching) method, etc., which results in that a trench 14 is formed in the insulating film 13.

Next, as shown in FIG. 6E, a second metal film 15 is deposited in the trench 14 and on the insulating film 13 by the PVD method and the CVD method, etc. The second metal film 15 is a film containing only the first metal element, or, a film containing the first and second metal elements and having a ratio of the second metal element to the first metal element smaller than that of the first metal film 12.

Next, as shown in FIG. 6F, the first silicide layer 5 is formed on the upper surface of the gate electrode 4 by a silicidation reaction between the second metal film 15 and the gate electrode 4 by carrying out the RTA at 400-500° C. Next, portions that are not reacted in the silicidation of the second metal film 15 are removed by the mixed solution of sulfuric acid and hydrogen peroxide solution, and the insulating film 13 is removed by the RIE method, thereby obtaining the semiconductor device 1 shown in FIG. 1.

According to the first embodiment, by differing the concentration of the second metal element in the second silicide layers 9 provided on the upper surface of the source/drain regions 8 from that in the first silicide layer 5 provided on the upper surface of the gate electrode 4, the first silicide layer 5 with low resistance is provided on the gate electrode 4 and the second silicide layers 9 with excellent film formability are provided on the source/drain regions 8. Thus, it is possible to obtain the semiconductor device 1 provided with silicide layers having appropriate characteristics according to a position where the silicide layer is provided.

### Second Embodiment

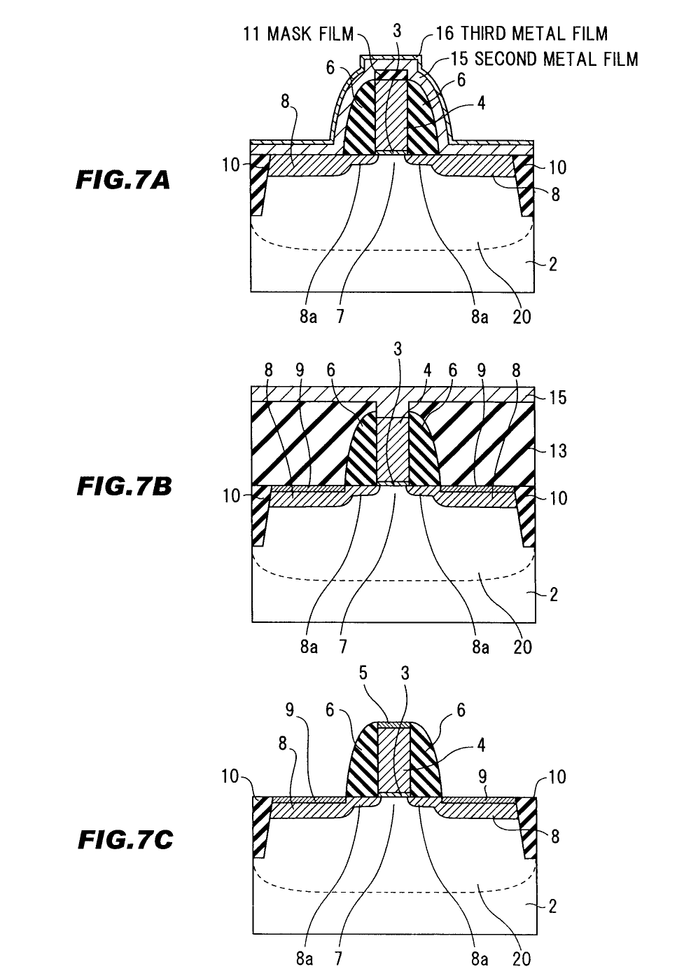

FIGS. 7A to 7C are cross sectional views showing processes for fabricating a semiconductor device according to a second embodiment. The second embodiment is different from the first embodiment in that, instead of forming the first metal film 12 and the second metal film 15 by sputtering, the second metal film 15 made of the first metal element such as Ni, etc., without containing the second metal element is formed by the CVD method, and a third metal film 16 made of the second metal element is further provided by the CVD method so as to cover the second metal film 15. Note that, the explanation will be omitted to simplify for the points same as the first embodiment.

Firstly, as shown in FIG. 7A, the second metal film 15 made of Ni, etc., is formed by the PVD method and the CVD method, etc., so as to cover the exposed portions of the upper surfaces of the source/drain regions 8, the element isolation region 10, the gate sidewalls 6 and the mask film 11. Next, the third metal film 16 made of the second metal element such as Pt, etc., is formed by the PVD method and the CVD method, etc., so as to cover the upper surface of the second metal film 15. Next, the second silicide layers 9 are formed on the upper surfaces of the source/drain regions 8 by a silicidation reaction between the second metal film 15, the third metal film 16 and the source/drain regions 8 by carrying out the RTA at 400-500° C. After this, a removal of unreacted portions of metal film, deposition of the insulating film 13 and formation of the trench 14 in the insulating film 13 are carried out in the same way as the first embodiment.

Next, as shown in FIG. 7B, the second metal film 15 is deposited in a trench on the gate electrode 4 and on the insulating film 13 by sputtering. Next, the first silicide layer 5 is formed on the upper surface of the gate electrode 4 by a silicidation reaction between the second metal film 15 and the upper surface of the gate electrode 4 by carrying out the RTA at 400-500° C.

Next, as shown in FIG. 7C, portions that are not reacted in the silicidation reaction of the second metal film 15 are removed by the mixed solution of sulfuric acid and hydrogen peroxide solution, and then, the insulating film 13 is removed by the RIE method.

According to the second embodiment, similarly to the first embodiment, it is possible to obtain the semiconductor device 1 provided with a silicide layer having appropriate characteristics according to a position where the silicide layer is provided.

Note that, in the second embodiment, although the process, in which the third metal film 16 made of the second metal element such as Pt, etc., is formed by the PVD method and the CVD method, etc., after forming the second metal film 15 made of Ni so as to cover the exposed portions of the upper surfaces of the source/drain regions 8, the element isolation region 10, the gate sidewalls 6 and the mask film 11, is explained, it is possible to generate the silicidation reaction between the third metal film 16, the second metal film 15 and the source/drain regions 8 by carrying out the RTA after forming the third metal film 16 and then subsequently forming the second metal film 15 so as to cover the upper surface of the third metal film 16.

### Third Embodiment

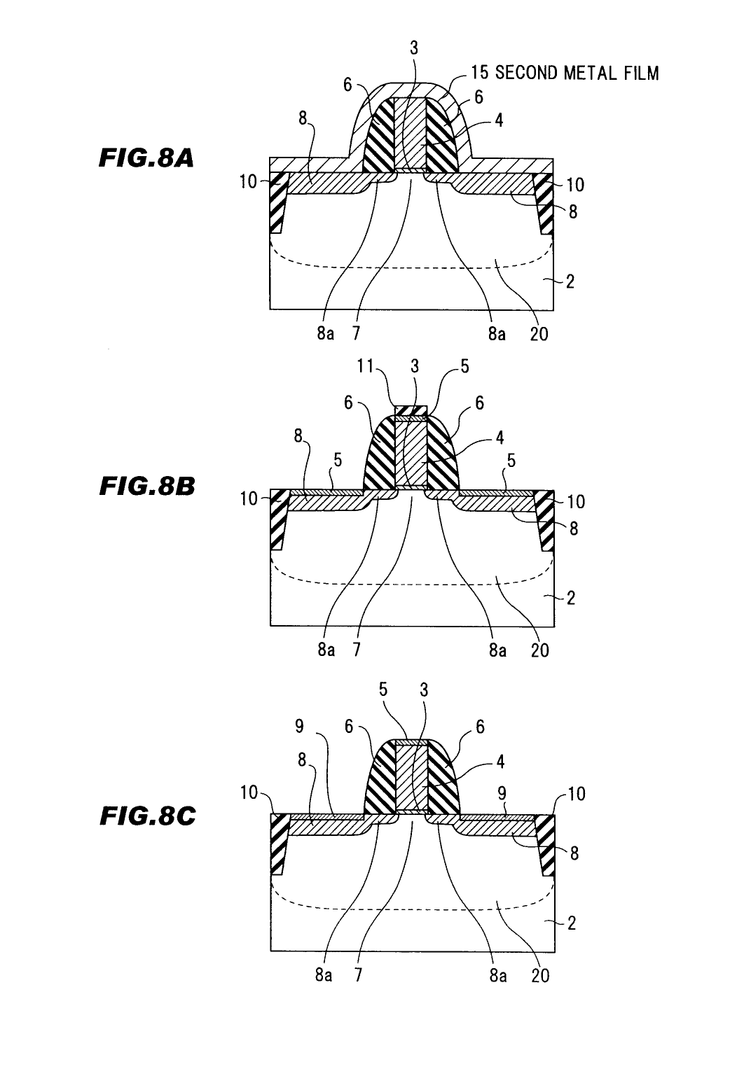

FIGS. 8A to 8C are cross sectional views showing processes for fabricating a semiconductor device according to a third embodiment. The third embodiment is different from the first embodiment in that, after forming the silicide layer by providing the second metal film 15 not containing the second metal element on the upper surfaces of the source/drain regions 8 and the gate electrode 4, the second metal element is mixed in the source/drain regions 8 by ion implantation. Note that, the explanation will be omitted to simplify for the points same as the first embodiment.

Firstly, as shown in FIG. 8A, the second metal film 15 made of Ni is formed by the PVD method and the CVD method, etc., so as to cover the exposed portions of the upper surfaces of the source/drain regions 8, the element isolation region 10, the gate sidewalls 6 and the gate electrode 4. Next, the first silicide layer 5 is formed on the upper surfaces of the gate electrode 4 and the source/drain regions 8 by a silicidation reaction between the second metal film 15 and the upper surface of the gate electrode 4 and between the second metal film 15 and the source/drain regions 8 by carrying out the RTA at 400-500° C.

Next, as shown in FIG. 8B, unreacted portions of second metal film 15 are removed and the mask film 11 is formed so as to cover the first silicide layer 5 that is provided on the upper surface of the gate electrode 4. Next, the second silicide layers 9 are formed on the source/drain regions 8 by ion implantation of the second metal element such as Pt, etc., into the source/drain regions 8.

Next, as shown in FIG. 8C, the mask film 11 provided on the first silicide layer 5 of the gate electrode 4 is removed.

According to the third embodiment, after forming the silicide layers on the gate electrode 4 and the source/drain regions 8, the second metal element is selectively ion-implanted into the source/drain regions 8. As a result, similarly to the first embodiment, the semiconductor device 1, which is provided with a silicide layer having appropriate characteristics according to a position where the silicide layer is provided, is obtained.

Note that, in the third embodiment, although it is explained that the second metal element is mixed in the second silicide layers 9 formed on the source/drain regions 8 by the ion implantation, for example, it is possible to generated the silicidation reaction between the third metal film 16 and the source/drain regions 8 by carrying out the RTA after forming the third metal film 16 made of the second metal element such as Pt, etc., by the PVD method and the CVD method, etc., so as to cover the exposed portions of the upper surfaces of the mask film 11, the source/drain regions 8, the element isolation region 10 and the gate sidewalls 6.

### Fourth Embodiment

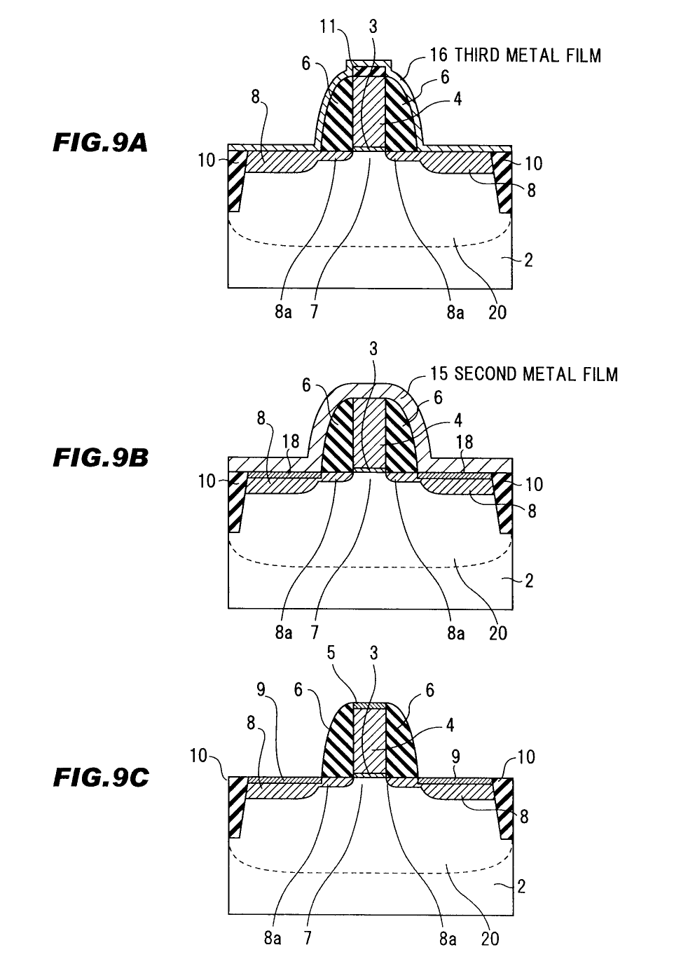

FIGS. 9A to 9C are cross sectional views showing processes for fabricating a semiconductor device according to a fourth embodiment. The fourth embodiment is different from the first embodiment in that, after forming the mask film 11 on the upper surface of the gate electrode 4 and subsequently forming the third metal film 16 made of the second metal element and then carrying out the silicidation reaction of the upper surfaces of the source/drain regions 8, the second metal film 15 is formed and the silicidation reaction of the upper surfaces of the gate electrode 4 and the source/drain regions 8 is carried out. Note that, the explanation will be omitted to simplify for the points same as the first embodiment.

Firstly, as shown in FIG. 9A, the mask film 11 is formed so as to cover the upper surface of the gate electrode 4. Next, the third metal film 16 made of the second metal element such as Pt, etc., is formed by the PVD method and the CVD method, etc., so as to cover the exposed portions of the upper surfaces of the mask film 11 on the gate electrode 4, the source/drain regions 8, the element isolation region 10 and the gate sidewalls 6. Next, third silicide layers 18 are formed on the upper surfaces of the source/drain regions 8 by a silicidation reaction between the third metal film 16 and the source/drain regions 8 by carrying out the RTA. Next, portions that are not reacted in the silicidation reaction of the third metal film 16 are removed by the mixed solution of sulfuric acid and hydrogen peroxide solution, and then, the mask film 11 on the gate electrode 4 is removed.

Next, as shown in FIG. 9B, the second metal film 15 made of Ni is formed by the PVD method and the CVD method, etc., so as to cover the exposed portions of the upper surfaces of the source/drain regions 8 having the third silicide layers 18, the element isolation region 10, the gate sidewalls 6 and the gate electrode 4. Next, the silicidation reaction is generated between the second metal film 15 and the upper surface of the gate electrode 4 and between the second metal film 15 and the third silicide layers 18 by carrying out the RTA at 400-500° C. Consequently, the first silicide layer 5 is formed on the upper surface of the gate electrode 4 and the second silicide layers 9 are formed on the upper surfaces of the source/drain regions 8.

Next, as shown in FIG. 9C, portions that are not reacted in the silicidation reaction of the second metal film 15 are removed by the mixed solution of sulfuric acid and hydrogen peroxide solution.

According to the fourth embodiment, after forming the third silicide layers 18 on the source/drain regions 8 using the third metal film 16 made of the second metal element such as Pt, etc., the silicidation reaction of the upper surfaces of the gate electrode 4 and the source/drain regions 8 is generated using the second metal film 15. As a result, similarly to the first embodiment, the semiconductor device 1, which is provided with a silicide layer having appropriate characteristics according to a position where the silicide layer is provided, is obtained.

### Other Embodiments

It should be noted that the embodiment is not intended to be limited to the above-mentioned first to fourth embodiments, and the various kinds of changes thereof can be implemented by those skilled in the art without departing from the gist of the invention.

In the manufacturing process in the embodiments, the first silicide layer 5 is formed after the second silicide layer 9 is formed. However, the first silicide layer 5 may be formed before the second silicide layer 9. Furthermore, the first silicide layer 5 and the second silicide layer 9 may be formed in the same manufacturing step.

In addition, the constituent elements of the above-mentioned embodiments can be arbitrarily combined with each other without departing from the gist of the invention.

What is claimed is:

1. A semiconductor device, comprising:
a semiconductor substrate;
a gate electrode formed on the semiconductor substrate via a gate insulating film;
a first silicide layer formed on the gate electrode;
a channel region formed in the semiconductor substrate below the gate electrode;
source/drain regions formed in regions in the semiconductor substrate, the regions sandwiching the channel region; and
second silicide layers formed on the source/drain regions and having an average grain size smaller than that of the first silicide layer or an average number of compositional boundaries in a crystal grain larger than that of the first silicide layer.

2. The semiconductor device according to claim 1, wherein the first silicide layer includes crystal grains containing a first crystallite that is a crystallite of a compound of a first metal element and Si; and
the second silicide layer includes crystal grains containing the first crystallite and a second crystallite that is a crystallite of a compound of a second metal element and Si.

3. The semiconductor device according to claim 2, wherein a ratio of a number of atoms of the second metal element to that of the first metal element in the second silicide layer is 7 at % or more.

4. The semiconductor device according to claim 2, wherein the first and second silicide layers include crystal grains containing the first and second crystallites; and
a ratio of a concentration of the second metal element to that of the first metal element in the second silicide layer is larger than a ratio of a concentration of the second metal element to that of the first metal element in the first silicide layer.

5. The semiconductor device according to claim 4, wherein the ratio of the concentration of the second metal element to that of the first metal element in the first silicide layer is 5 at % or less.

6. The semiconductor device according to claim 2, wherein the first silicide layer does not include the second metal element.

7. The semiconductor device according to claim 2, wherein a crystal structure of the compound of the first metal element and Si is equivalent to that of a compound of the second metal element and Si.

8. The semiconductor device according to claim 2, wherein an atomic radius of the second metal element is larger than that of the first metal element.

9. The semiconductor device according to claim 8, wherein the first and second metal elements are elements in different periods.

10. The semiconductor device according to claim 9, wherein the first metal element is a fourth-period element and the second metal element is a fifth or sixth-period element.

11. The semiconductor device according to claim 10, wherein the first metal element is an element selected from Ti, V, Co and Ni, and the second metal element is an element selected from Ru, Rh, Pd, In, Ir and Pt.

12. The semiconductor device according to claim 2, wherein the average grain size of the crystal grains in the second silicide layer is 100 nm or less.

13. The semiconductor device according to claim 12, wherein a grain size is 20 nm or less in a region of 80% or more of the second silicide layer.

14. A method of fabricating a semiconductor device, comprising:
forming a gate electrode on a semiconductor substrate via a gate insulating film;
selectively forming a first silicide layer on the gate electrode;
forming a channel region in the semiconductor substrate below the gate electrode;
forming source/drain regions in regions in the semiconductor substrate, the regions sandwiching the channel region; and
selectively forming second silicide layers on the source/drain regions,
wherein the second silicide layers have an average grain size smaller than that of the first silicide layer or an average number of compositional boundaries in a crystal grain larger than that of the first silicide layer.

15. The method of fabricating a semiconductor device according to claim 14, wherein the first silicide layer includes crystal grains containing a first crystallite that is a crystallite of a compound of a first metal element and Si; and
the second silicide layer includes crystal grains containing the first crystallite and a second crystallite that is a crystallite of a compound of a second metal element and Si.

16. The semiconductor device according to claim 15, wherein the second silicide layers are formed by reacting a metal film containing the first and second metal elements with the source/drain regions; and
the first silicide layer is formed by reacting a metal film containing the first metal element with the gate electrode.

17. The semiconductor device according to claim 15, wherein the second silicide layers are formed by reacting a laminated film with the source/drain regions, the laminated film comprising a metal film containing the first metal element and a metal film containing the second metal element; and
the first silicide layer is formed by reacting the metal film containing the first metal element with the gate electrode.

18. The semiconductor device according to claim 15, wherein, after reacting a metal film containing the first metal element with the source/drain regions and the gate electrode, the first and second silicide layers are formed by implanting the second metal element into the source/drain regions.

19. The semiconductor device according to claim 15, wherein, after reacting a metal film containing the second metal element with the source/drain regions, the first and second silicide layers are formed by reacting a metal film containing the first metal element with the source/drain regions and the gate electrode.

20. The semiconductor device according to claim 15, wherein the second silicide layers are formed by reacting a metal film containing the first and second metal elements with the source/drain regions; and
the first silicide layer is formed by reacting another metal film with the gate electrode, the another metal film containing the first and second metal elements and having a ratio of the second metal element to the first metal element smaller than that of the metal film.
